(19) United States
(12) Patent Application Publication
(10) Pub. No.: US 2025/0343526 A1
(43) Pub. Date: Nov. 6, 2025

(54) APERTURE CONTROLLED METASURFACES FOR SELECTIVE BEAMFORMING

(71) Applicant: Dell Products L.P., Round Rock, TX (US)

(72) Inventors: Tejinder Singh, Manotick (CA); Kan Wang, Ottawa (CA); Navjot Kaur Khaira, Manotick (CA)

(21) Appl. No.: 18/656,454

(22) Filed: May 6, 2024

(51) Int. Cl. H03H 9/02; H03H 9/05; H03H 9/25

(52) U.S. Cl. CPC H03H 9/02574; H03H 9/0542; H03H 9/25

(57) ABSTRACT

The technology described herein is generally directed towards reconfiguring apertures of reconfigurable intelligent surfaces (metasurfaces) using surface acoustic waves to change metal-insulator-transition material (e.g., vanadium dioxide (VO2)) to a lower resistance state. Reconfigurability of unit cells' resonator apertures is achieved by generating surface acoustic waves per unit cell, via a unit cell capacitor (e.g., interdigitated capacitor) coupled to a low frequency control signal. The presence of the surface acoustic waves stresses the (e.g., VO2) material enabling current flow on the aperture (hence resonance) when subject to an incoming electromagnetic wave. Removal of the control signal results in the metal-insulator-transition material (e.g., VO2) changing to a higher resistance state that blocks the current flow (no resonance). The VO2-based design can be used in a single metasurface configuration, or in a stack of reconfigurable metasurfaces to select among different metasurface configurations that facilitate different beam shaping, beam gain, and/or other beam characteristics.

### BACKGROUND

Reconfigurable intelligent surfaces, alternatively referred to as metasurfaces, are specifically designed manmade surfaces of electromagnetic material that are electronically controlled with integrated electronics. These thin two-dimensional metasurfaces can tune an incoming electromagnetic wave's key properties, such as amplitude, phase, and polarization, as the electromagnetic wave is reflected or refracted by the surface. In other words, a reconfigurable intelligent surface is a two-dimensional surface whose surface can be electronically altered such that it changes the characteristics of any incoming electromagnetic wave, including the wave's phase.

Each metasurface typically is made up of (possibly up to) dozens, hundreds or thousands of unit-cells (sometimes referred to as elements), and because the unit cells can be controlled, reconfigurable intelligent surfaces can provide programmable and smart wireless environments. For example, one scenario is to use such a surface to intelligently reconfigure wireless communications. More particularly, objects in the path of a wireless signal, such as buildings and trees, can block wireless communication signals at higher frequencies, such as millimeter-wave frequency bands (24.5 GHz-52.6 GHZ), which are expected to move upwards to sub-terahertz bands. This can be overcome by installing a large number of base stations to provide coverage to otherwise blocked areas, but doing so would increase the infrastructure costs many times. Instead, a relatively inexpensive metasurface can be installed at various locations to reflect and/or refract higher frequency signals to otherwise blocked or weak coverage areas.

### BRIEF DESCRIPTION OF THE DRAWINGS

The technology described herein is illustrated by way of example and not limited in the accompanying figures in which like reference numerals indicate similar elements and in which:

FIG. 1A is a top view representation of example unit cells that each have a ring resonator configured from metal-insulator-transition material and a capacitor-based surface acoustic wave generator, in accordance with various aspects and implementations of the subject disclosure, in accordance with various aspects and implementations of the subject disclosure.

FIG. 1B is a cross-sectional side view representation of an example unit cell, e.g., corresponding to one of the unit cells of FIG. 1A, in accordance with various aspects and implementations of the subject disclosure.

FIG. 2A is an isometric view representation of a top surface of an example reconfigurable intelligent surface of unit cells (e.g., with each unit cell corresponding to the example unit cell of FIG. 1A), in accordance with various aspects and implementations of the subject disclosure.

FIG. 2B is an isometric view representation of a bottom surface of the example reconfigurable intelligent surface, along with a zoomed-in representation of part of the bottom surface example showing example coplanar waveguide lines, in accordance with various aspects and implementations of the subject disclosure.

FIG. 3 is a top view representation of an example unit cell with a rectangular ring resonator illustrating high current density on two opposite sides of the rectangular ring resonator, in which the flow of current enables the resonator behavior, in accordance with various aspects and implementations of the subject disclosure.

FIG. 4 is a top view representation of the example unit cell of FIG. 3 with the rectangular ring resonator configured from metal-insulator-transition material, showing an aperture portion of the rectangular ring resonator in a lower resistance state that facilitates current flow when a surface acoustic wave, sourced by an interdigitated capacitor (also shown zoomed-in), is traveling through the rectangular ring resonator, in accordance with various aspects and implementations of the subject disclosure.

FIG. 5 is a top view representation of the example unit cell of FIG. 3 showing the aperture portion of the rectangular ring resonator depicted in a higher resistance state that blocks current flow when there is no surface acoustic wave, in accordance with various aspects and implementations of the subject disclosure.

FIG. 6 is a block diagram representation of example reconfigurable surfaces having unit cells controlled by the presence or absence of surface acoustic waves to controllably redirect impinging electromagnetic waves in various directions, in accordance with various aspects and implementations of the subject disclosure.

FIG. 7 is a representation of example stacked reconfigurable intelligent surfaces, each with reconfigurable functionality by selection of one or more of the reconfigurable intelligent surfaces with respect to surface acoustic wave generation, in accordance with various aspects and implementations of the subject disclosure.

FIGS. 8-10 are example representations of beam angle and gain plots corresponding to selection of different reconfigurable intelligent surfaces, such as from the example stacked reconfigurable intelligent surfaces of FIG. 7, in accordance with various aspects and implementations of the subject disclosure.

FIG. 11 is a flow diagram showing example operations related to changing a state of a unit cell of a reconfigurable intelligent surface from a non-resonating state to a resonating state, in accordance with various aspects and implementations of the subject disclosure.

### DETAILED DESCRIPTION

The technology described herein is generally directed towards unit cells of a reconfigurable intelligent surface in which a unit cell's resonator includes metal-insulator-transition material. The unit cell's resonator is controlled by the presence or absence of a surface acoustic wave, which changes an aperture portion of the resonator between a lower resistance state and a higher resistance state, respectively. In the lower resistance state in which the surface acoustic wave is present, the resonator resonates to redirect an impinging electromagnetic wave in a target direction; when the surface acoustic wave is removed, the resonator does not resonate.

There is thus described the selective reconfiguration of the apertures of reconfigurable intelligent surfaces (metasurfaces) using acoustic surface waves on metal-insulator-transition material. This facilitates a straightforward implementation and design of such metasurfaces. Also described is a stack of aperture controlled metasurfaces, providing an implementation and design having dynamic switching functionality with respect to parameters/characteristics of a beam redirected from the stack of metasurfaces, e.g., beam steering angle, gain, polarization and so on.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and reconfigurable intelligent surfaces in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

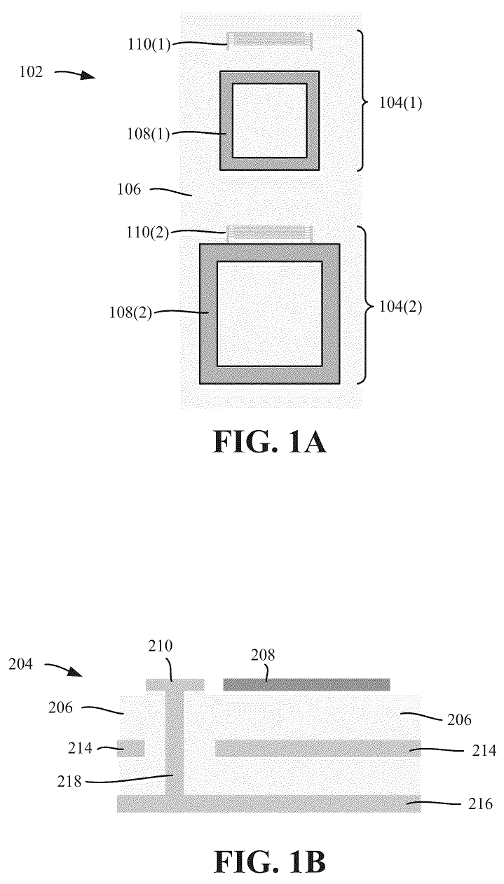

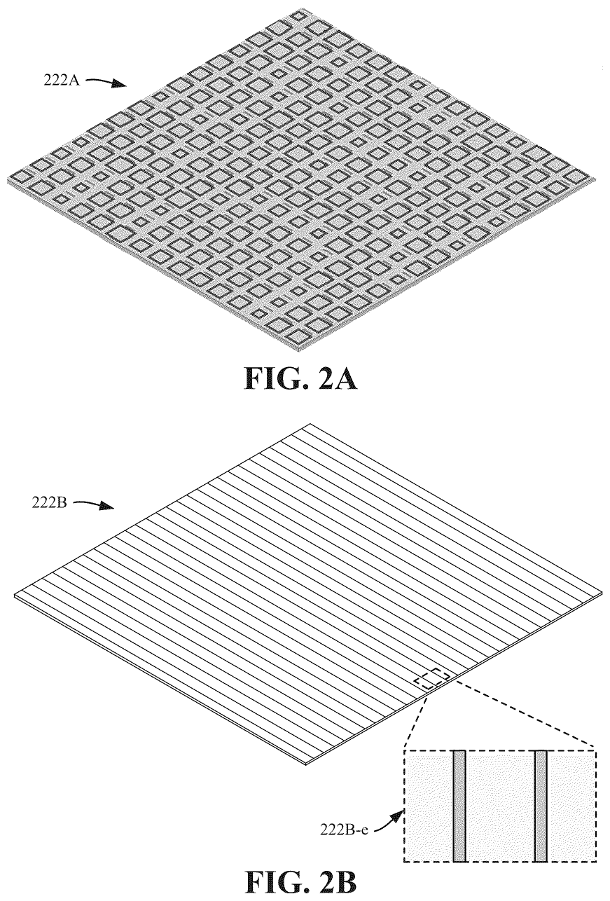

FIG. 1A is a top view representation of a part of a reconfigurable surface 102 showing two unit-cells 104(1) and 104(2) atop a substrate 106. The unit cells 104(1) and 104(2) include rectangular (e.g., square) ring-type resonators 108(1) and 108(2), respectively, formed from metal-insulator-transition material, such as vanadium dioxide. In this example, the resonators 108(1) and 108(2) are of different sizes corresponding to different resonator properties, although it should be understood that this is a nonlimiting example.

In FIG. 1A, the two unit-cells 104(1) and 104(2) are coupled to surface acoustic wave generators 110(1) and 110(2), respectively, which can be considered part of their respective unit cells 104(1) and 104(2). In one example implementation, the surface acoustic wave generators 110(1) and 110(2) include interdigitated capacitors, positioned generally parallel to sides of their respective resonators 108(1) and 108(2), that independently source the surface acoustic waves when an appropriate low frequency signal is applied thereto. As will be understood, the application of the signal and the resultant surface acoustic wave changes the state of an aperture portion of the resonator (e.g., 108(1)) to a low resistance state that enables the resonator to resonate when an electromagnetic wave, at a frequency corresponding to the resonator's resonance frequency, is impinging on the unit cell 104(1).

The metal-insulator-transition material can be made from vanadium oxide-based alloys, such as vanadium dioxide, often abbreviated as VO2. VO2 is a compound composed of vanadium and oxygen atoms. One of the properties of VO2 is its ability to undergo a phase transition at a specific critical temperature. This phase transition leads to significant changes in its electrical and optical properties, making it a useful material for various applications, including its use as a thermo-resistor. As the temperature of VO2 crosses a critical point known as the metal-insulator transition temperature (around 68 degrees Celsius or 154 degrees Fahrenheit), the material undergoes a rapid change in its electrical resistance. Indeed, a significant property of VO2 is its temperature-dependent resistance. Below the transition temperature, it behaves as an insulator with high electrical resistance. However, when heated above this temperature, it transforms into a metallic state with significantly lower resistance. This property can be harnessed in thermo-resistors, sensors, and other devices to detect temperature changes accurately.

Moreover, VO2's resistance also can be influenced by mechanical factors such as stress and strain. The application of stress or strain to VO2 can cause further variations in its electrical resistance. These characteristics make VO2 a versatile material traditionally used in applications where precise control and sensing of temperature, stress, and strain are essential. Notwithstanding, described herein is using the inverse relationship, in which stress is controllably applied, via a surface acoustic wave, to change the VO2's electrical property so as to reconfigure the aperture geometry of a unit cell.

FIG. 1B shows a cross-sectional view of an example design of part of a unit-cell 204, including the metal-insulator-transition material 208 (e.g., VO2) used for the ring resonator, atop a substrate 206. The capacitor 210, e.g., an interdigitated capacitor formed from copper, is also atop the substrate 206, positioned adjacent to the metal-insulator-transition material 208. The ground portion 214 of the unit cell 204 is beneath and generally parallel to the metal-insulator-transition material 208, supported within the substrate 206. In one example implementation, the substrate 206 can be (at least in part) a piezoelectric substrate that operates as part of the surface acoustic wave generator when an electrical voltage is applied to the piezoelectric substrate.

A coplanar waveguide line 216 for the unit cell 204, beneath the substrate 206, provides the signal to the positive terminal of the capacitor 210, through a via 218 that passes through the substrate 206 and ground plane 214, when selectively-controlled to generate the surface acoustic wave. A similar via (not explicitly shown) is coupled to the negative terminal of the capacitor 210.

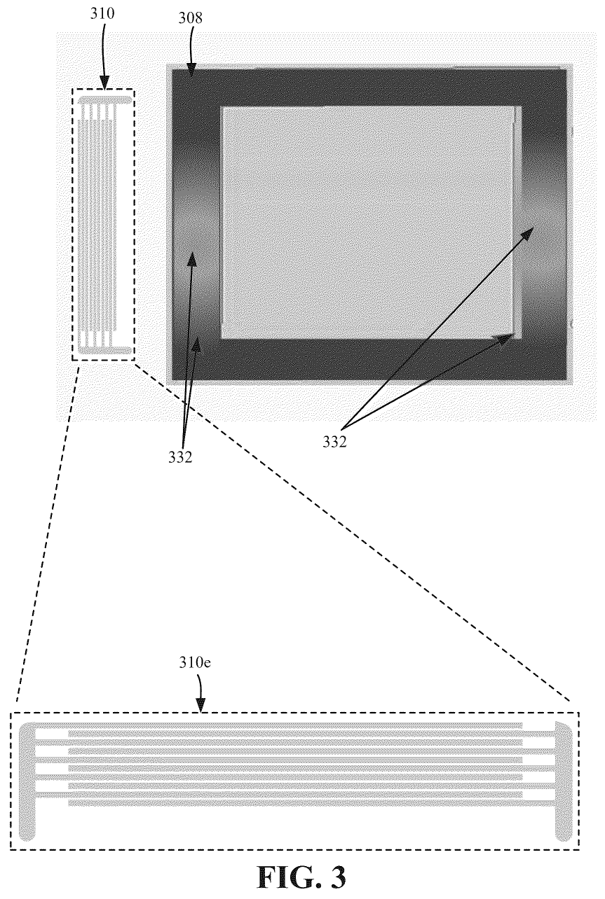

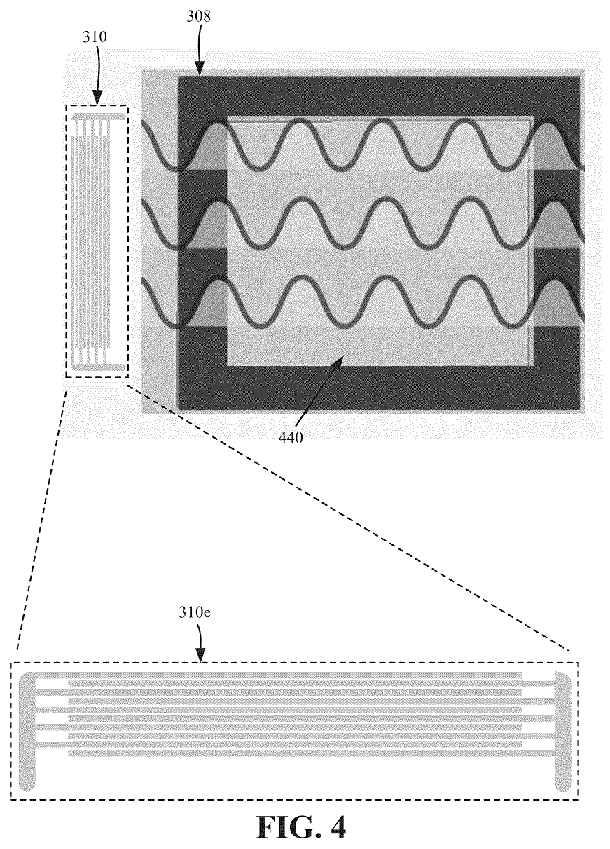

FIG. 2A depicts an example reconfigurable intelligent surface (top view 222A) showing a 15×15 array of unit-cells, e.g., of two different sizes (the different sizes are non-symmetrically distributed in this example), that can be controlled with respect to the aperture of the reconfigurable intelligent surface 222 as described herein. FIG. 2B depicts the bottom view 222B of the unit cell, showing coplanar waveguide lines (e.g., the line 216 of FIG. 1B) at the bottom layer, e.g., one line for the positive terminals of each column of the unit cells' capacitors, and one for the negative terminals. In this way, a column of unit cells' capacitors can be controllably actuated with a low frequency signal for the capacitor to change the states of the unit cells of that column to the lower resistance state by the capacitors' generation of the surface acoustic waves. Alternatively, the entire array of unit cells can be arranged to resonate or not based on the presence or absence of the surface acoustic wave control signal. An enlarged portion 222B-e of the bottom layer view 222B showing a pair of coplanar waveguide lines is also shown in FIG. 2B.

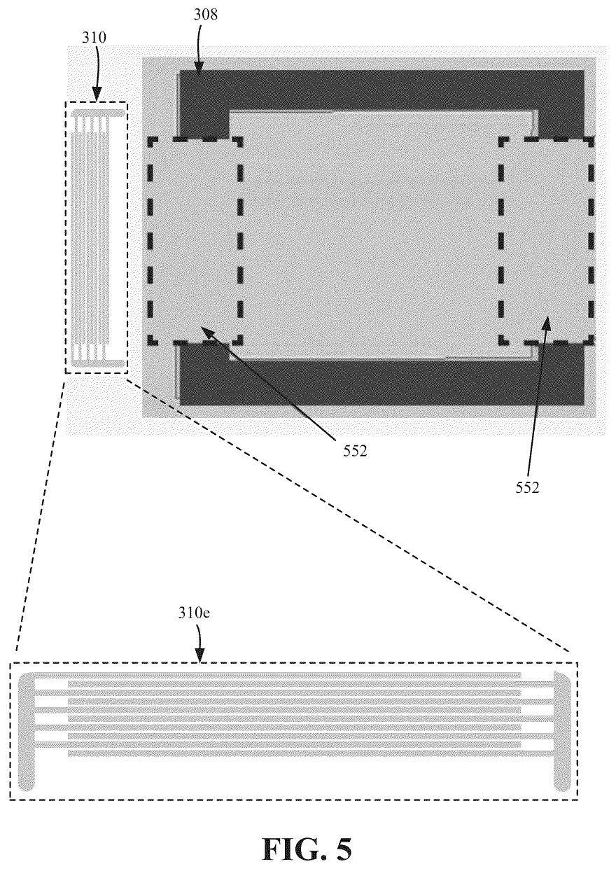

The ability of the proposed aperture reconfiguration is based on manipulating the current density flowing on the unit-cell aperture, as shown in FIGS. 3-5. The technology described herein leverages the dependency of vanadium dioxide's resistance to stress, facilitating a dynamic method of controlling aperture current density. In FIG. 3, the high current density is illustrated by the lighter portions 332 of the rectangular ring resonator aperture 308.

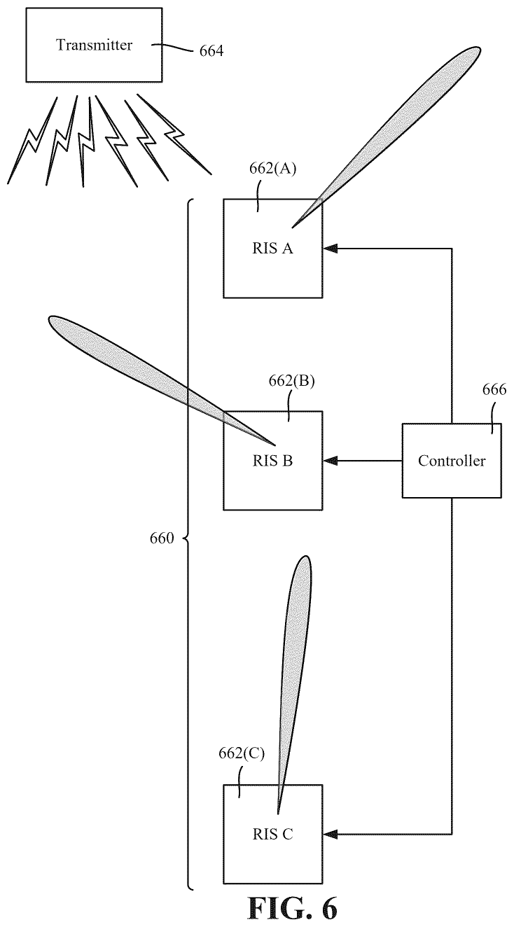

When the enable signal is on, as shown in FIGS. 3 and 4 a surface acoustic wave 440 generates (FIG. 4), enabling the current flow on the rectangular ring resonator aperture 308. FIGS. 3 and 4 also show an enlarged view 310e of the interdigitated capacitor 310, where the capacitance is realized by the spacing in between the conductive “fingers” of the interdigitated capacitor 310 as shown. When the current flow is enabled by the presence of the surface acoustic wave 440, the aperture of the unit cell resonator has a lower resistance when the surface acoustic wave is traveling through it, whereby the unit-cell functionality is maintained, such that the resonator aperture 308 resonates in response to an electromagnetic wave having a frequency corresponding to the resonance frequency of the rectangular ring resonator aperture 308.

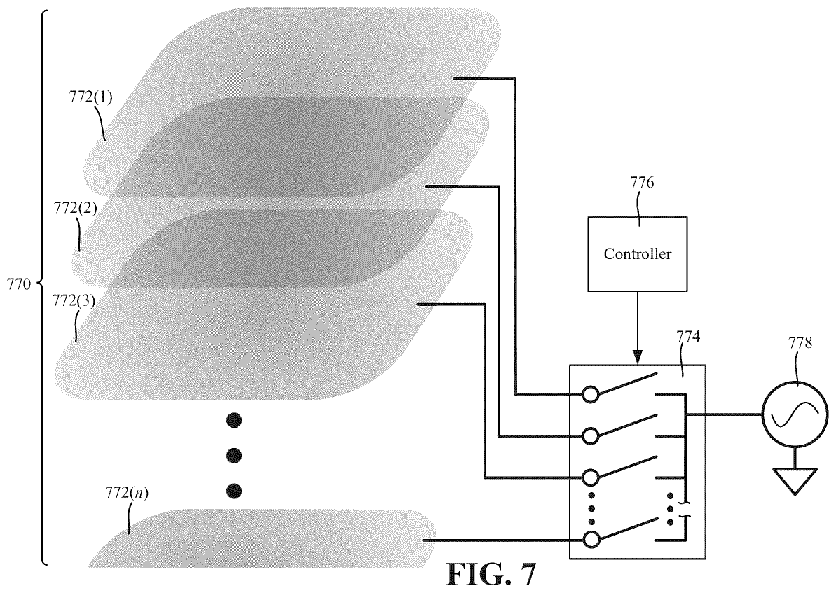

When the enable signal is off as shown in FIG. 5, the acoustic surface wave is silenced, whereby the high resistance state of the VO2 in the (previously lower-resistance) aperture portion 550 denies the current flow on the resonator aperture 308. In this state, the unit-cell is disabled and does not resonate for manipulation of incoming electromagnetic waves.

To summarize, a metasurface design with aperture reconfiguration is realized as shown in FIG. 2A. The control signals for the surface acoustic waves, when enabled, are fed through coplanar waveguide lines in the bottom layer of the metasurface (FIG. 2B), travelling through vias and reaching the capacitors for wave generation. The resulting surface acoustic wave then reconfigures the VO2 apertures into their lower resistance states as described with reference to FIGS. 3 and 4. This design for a single surface is capable of enabling or disabling an entire metasurface (or selected columns of unit cells therein), with a functionality like a power button for the entire metasurface (or per column).

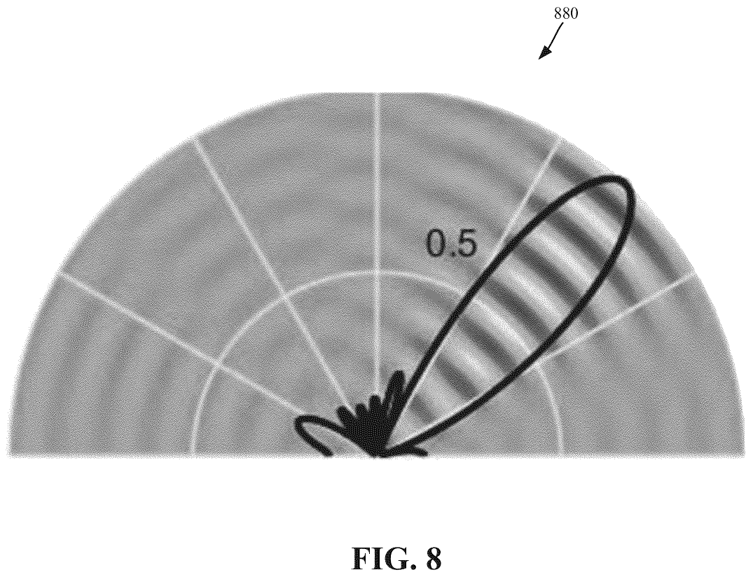

By stacking the single surface design into a stack of metasurfaces, more flexible control can be realized, as depicted in FIGS. 6-10. In FIG. 6, consider that a stack 660 of metasurfaces 662(1)-662(3) receive electromagnetic waves from a transmitter 664. In FIG. 6, the metasurface 662(A), if enabled via a control signal from a controller 666, reflects the beam in a first beam direction. Similarly, if enabled the metasurface 662(B) reflects the beam in a second, different beam direction, as does the metasurface 662(C) with respect to reflecting the beam in a third, yet another different beam direction when enabled.

Although FIG. 6 depicts examples of beams being reflected in different directions, the technology described herein can also be used for determining other beam parameters. Nonlimiting examples of such beam parameters include a beam-steering angle, a beam gain, a beam frequency, a beam bandwidth, or a beam polarization.

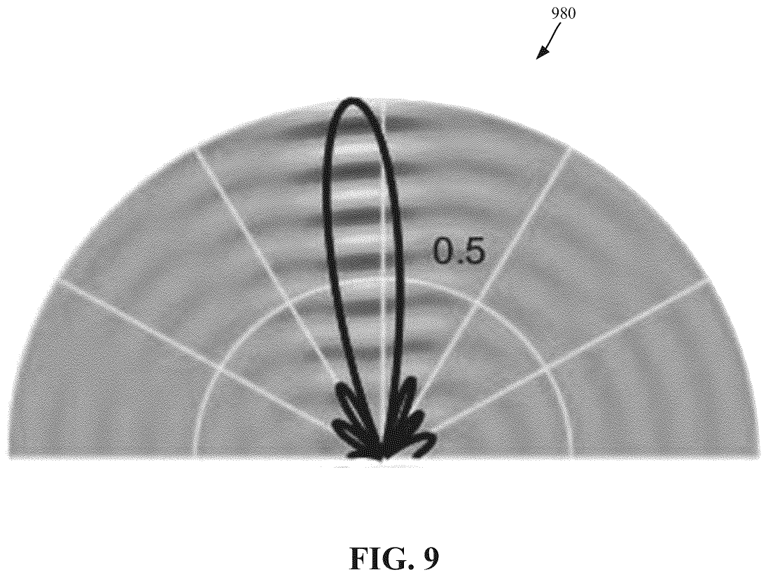

By way of example, FIG. 7 shows a stack 770 of metasurfaces 772(1)-722(n) with their signal lines coupled to a switch 774 that is controlled by a controller 776. The stack 770 of metasurfaces 772(1)-722(n) provide reconfigurable functionality by selection of one or more surfaces by the controller 776 via the switch 774, wherein the switch is coupled to a low frequency signal source 778 for surface acoustic wave generation by the unit cells of the metasurfaces 772(1)-722(n).

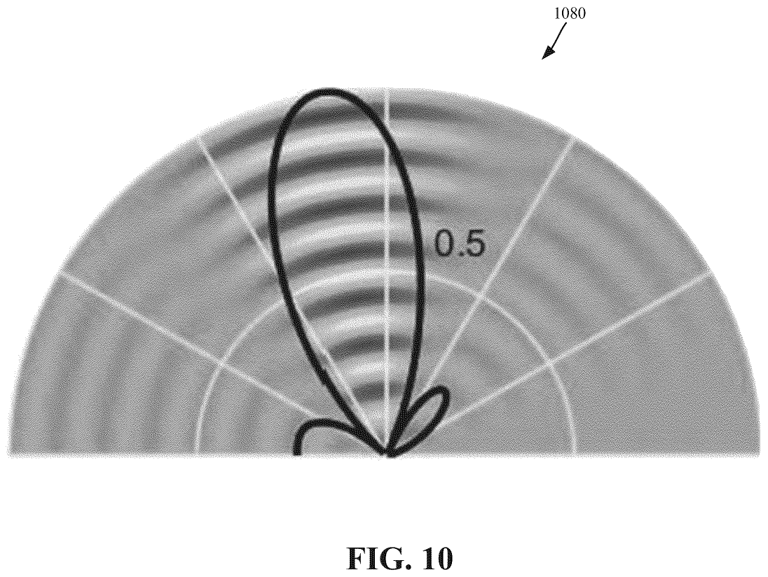

FIGS. 8-10 show beams with different characteristics based on the switch selection. For example, consider that the metasurface 772(1), when coupled to the low frequency signal source 778 by the switch 774 as controlled by the controller 776, results in the beam shown in the plot 880 of FIG. 8, having a 70 degree beam steering angle and a 20 dBi gain. In a further example, the metasurface 772(2), when coupled to the low frequency signal source 778, results in the beam shown in the plot 980 of FIG. 9, having a 10 degree beam steering angle and a 20 dBi gain. Similarly, the metasurface 772(3), when coupled to the low frequency signal source 778, results in the beam shown in the plot 1080 of FIG. 10, having a 20 degree beam steering angle and a 10 dBi gain.

Examples of the technology described herein can be embodied in a controllable resonator device. The controllable resonator device can include metal-insulator-transition material configured as a resonator, the resonator including an aperture portion of the metal-insulator-transition material. The controllable resonator device further can include a surface acoustic wave generator that, in response to presence of an activation signal, outputs surface acoustic waves that travel through the metal-insulator-transition material to reconfigure the aperture portion into a low resistance state in which the controllable resonator device resonates, in response to an impinging electromatic wave having a frequency corresponding to a resonating frequency of the resonator, to redirect a redirected instance of the impinging electromatic wave, and that, in response to absence of the activation signal, halts the output of the surface acoustic wave to the metal-insulator-transition material to reconfigure the aperture portion into a high resistance state in which the tunable resonator device does not resonate in response to the impinging electromatic wave.

The surface acoustic waves can travel on the surface of a substrate beneath the metal-insulator-transition material to travel through the metal-insulator-transition material. The substrate can include a piezoelectric substrate that operates as part of the surface acoustic wave generator when an electrical voltage is applied to the piezoelectric substrate.

The surface acoustic wave generator can include an interdigitated capacitor comprising conductive fingers.

The metal-insulator-transition material can be shaped as a rectangular ring resonator, and the aperture portion can be formed within opposite sides of the rectangular ring resonator that are parallel or substantially parallel to the conductive fingers of the interdigitated capacitor.

The metal-insulator-transition material can include a vanadium oxide-based alloy.

In the low resistance state, the controllable resonator can resonate to determine a first phase shift of a unit cell of a reconfigurable intelligent surface, and in the high resistance state, the controllable resonator does not resonate.

The controllable resonator device can be incorporated into a unit cell, and the unit cell can be part of a group of reconfigurable unit cells that are collectively arranged into a reconfigurable intelligent surface.

The reconfigurable intelligent surface can redirect the redirected instance by determining at least one of: a beam-steering angle of the redirected instance, a gain of the redirected instance, a frequency of the redirected instance, a bandwidth of the redirected instance, or a polarization of the redirected instance.

The redirected instance can be a first redirected instance of the impinging electromatic wave, the reconfigurable intelligent surface can be a first reconfigurable intelligent surface that redirects the first redirected instance of the impinging electromatic wave at a first beam direction; there can be a second reconfigurable intelligent surface, stacked below the first reconfigurable intelligent surface, that can redirect a second redirected instance of the impinging electromatic wave at a second beam direction that is different from the first beam direction.

The redirected instance can be a first redirected instance, the reconfigurable intelligent surface can be a first reconfigurable intelligent surface that redirects the first redirected instance of the impinging electromatic wave at a first beam direction with a first gain value; there can be a second reconfigurable intelligent surface, stacked below the first reconfigurable intelligent surface, that redirects a second redirected instance of the impinging electromatic wave at a second beam direction with a second gain value, in which the first beam direction is different from the second beam direction, and the first beam gain value is different from the second beam gain value.

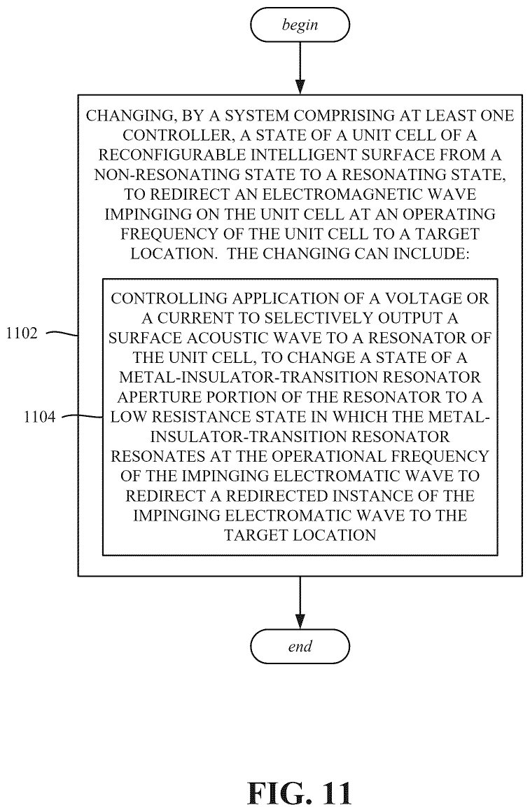

One or more example embodiments, such as corresponding to example operations of a method, are represented in FIG. 11. Example operation 1102 represents changing, by a system comprising at least one controller, a state of a unit cell of a reconfigurable intelligent surface from a non-resonating state to a resonating state, to redirect an electromagnetic wave impinging on the unit cell at an operating frequency of the unit cell to a target location. The changing can include example operation 1104, which represents controlling application of a voltage or a current to selectively output a surface acoustic wave to a resonator of the unit cell, to change a state of a metal-insulator-transition resonator aperture portion of the resonator to a low resistance state in which the metal-insulator-transition resonator resonates at the operational frequency of the impinging electromatic wave to redirect a redirected instance of the impinging electromatic wave to the target location.

Further operations can include, changing, by the system, the state of the unit cell from the resonating state to the non-resonating state, which can include removing the application of the voltage or the current to halt the selective output of the surface acoustic wave to the resonator, to change the state of a metal-insulator-transition resonator aperture portion to a high resistance state in which metal-insulator-transition resonator does not resonate at the operational frequency of the impinging electromatic wave.

The unit cell can be part of a group of respective unit cells of a reconfigurable intelligent surface, and the at least one controller can control respective low resistance or high resistance states of respective metal-insulator-transition resonator aperture portions of the respective unit cells to controllably create constructive interference of respective redirected instances that together reflect the impinging electromatic wave as a beam in a controlled reflection direction with a controlled gain.

Examples of the technology described herein can be embodied in a unit cell. The unit cell can include a ring resonator that includes metal-insulator-transition material, a substrate beneath the ring resonator, and a surface acoustic wave generator. The surface acoustic wave generator can be controlled to output a surface acoustic wave to travel atop the substrate and through the metal-insulator-transition material to change an aperture portion of the ring resonator to a low resistance state in which the ring resonator resonates in response to an electromagnetic wave impinging on the unit cell at a frequency corresponding to a resonating frequency of the ring resonator. The surface acoustic wave generator can be controlled to halt the output of the surface acoustic wave to change the aperture portion of the ring resonator to a high resistance state in which the ring resonator does not resonate in response to the electromagnetic wave impinging on the unit cell.

The surface acoustic wave generator can include an interdigitated capacitor comprising interleaved fingers.

The ring resonator can be rectangular, the surface acoustic wave generator can include an interdigitated capacitor positioned parallel or substantially parallel to opposite sides of the ring resonator, and the aperture portion of the ring resonator can correspond to the opposite sides of the ring resonator.

The unit cell can be a respective unit cell of a group of respective unit cells of a reconfigurable intelligent surface, and respective surface acoustic wave generators of the respective unit cells can be independently controllable to redirect the electromagnetic wave impinging on the reconfigurable intelligent surface as a beam having beam parameters determined by respective low resistance or high resistance states of the respective unit cells.

The beam parameters can include at least one of: a beam-steering angle, a beam gain, a beam frequency, a beam bandwidth, or a beam polarization.

The reconfigurable intelligent surface can be a first reconfigurable intelligent surface of respective first unit cells, the beam can be a first beam having first beam parameters, the respective low resistance or high resistance states can be respective first low resistance or high resistance states of the respective first unit cells. There can be a second reconfigurable intelligent surface, stacked below the first reconfigurable intelligent surface, that includes respective second unit cells that are independently controllable from the respective first unit cells to redirect the electromagnetic wave impinging on the second reconfigurable intelligent surface as a second beam having second beam parameters determined by respective second low resistance or high resistance states of the respective second unit cells of the second reconfigurable intelligent surface.

As can be seen, the technology described herein is based on VO2-based reconfiguration of unit cells, which leverages the material's property of having its resistance dependent on stress. By introducing surface acoustic waves, the resistance of VO2 can be dynamically altered, allowing for rapid and precise reconfiguration of the metasurface.

The benefits and advantages of the technology described herein include, but are not limited to, high speed reconfiguration, as VO2-based reconfiguration can be very fast, due to relying on the propagation of surface acoustic waves, which travel at high speeds. Further, compared to other metasurface technologies, VO2-based reconfiguration may need less power, particularly when compared to PIN diodes-based systems. The technology described herein is conceptually straightforward, relying on the intrinsic properties of VO2 and the generation of surface acoustic waves. VO2's rapid response to stress makes it suitable for dynamic control of metasurfaces, allowing for real-time adjustments to incoming electromagnetic waves. Further, the technology is low cost, as there are no surface-mount components; instead, the geometry is simply printed on the circuit board, which means a simple manufacturing process and reduced cost for fabrication.

In summary, aperture reconfiguration based on VO2 as described herein offers advantages in terms of speed, power efficiency, temperature tolerance, simplicity, and dynamic control. These advantages make it a competitive technology for future applications in telecommunications, beamforming, and wave manipulation technologies.

What has been described above includes mere examples. It is, of course, not possible to describe every conceivable combination of components, materials or the like for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A controllable resonator device, comprising:
metal-insulator-transition material configured as a resonator, the resonator comprising an aperture portion of the metal-insulator-transition material; and
a surface acoustic wave generator that,
in response to presence of an activation signal, outputs surface acoustic waves that travel through the metal-insulator-transition material to reconfigure the aperture portion into a low resistance state in which the controllable resonator device resonates, in response to an impinging electromatic wave having a frequency corresponding to a resonating frequency of the resonator, to redirect a redirected instance of the impinging electromatic wave; and
in response to absence of the activation signal, halts the output of the surface acoustic wave to the metal-insulator-transition material to reconfigure the aperture portion into a high resistance state in which the tunable resonator device does not resonate in response to the impinging electromatic wave.

2. The controllable resonator device of claim 1, wherein the surface acoustic waves travel on a surface of a substrate beneath the metal-insulator-transition material to travel through the metal-insulator-transition material.

3. The controllable resonator device of claim 2, wherein the substrate comprises a piezoelectric substrate that operates as part of the surface acoustic wave generator when an electrical voltage is applied to the piezoelectric substrate.

4. The controllable resonator device of claim 1, wherein the surface acoustic wave generator comprises an interdigitated capacitor comprising conductive fingers.

5. The controllable resonator device of claim 4, wherein the metal-insulator-transition material is shaped as a rectangular ring resonator, and wherein the aperture portion is formed within opposite sides of the rectangular ring resonator that are parallel or substantially parallel to the conductive fingers of the interdigitated capacitor.

6. The controllable resonator device of claim 1, wherein the metal-insulator-transition material comprises a vanadium oxide-based alloy.

7. The controllable resonator device of claim 1, wherein, in the low resistance state, the controllable resonator resonates to determine a first phase shift of a unit cell of a reconfigurable intelligent surface, and wherein, in the high resistance state, the controllable resonator does not resonate.

8. The controllable resonator device of claim 1, wherein the controllable resonator device is incorporated into a unit cell, and wherein the unit cell is part of a group of reconfigurable unit cells that are collectively arranged into a reconfigurable intelligent surface.

9. The controllable resonator device of claim 8, wherein the reconfigurable intelligent surface redirects the redirected instance by determining at least one of: a beam-steering angle of the redirected instance, a gain of the redirected instance, a frequency of the redirected instance, a bandwidth of the redirected instance, or a polarization of the redirected instance.

10. The controllable resonator device of claim 8, wherein the redirected instance is a first redirected instance of the impinging electromatic wave, wherein the reconfigurable intelligent surface is a first reconfigurable intelligent surface that redirects the first redirected instance of the impinging electromatic wave at a first beam direction, and further comprising a second reconfigurable intelligent surface, stacked below the first reconfigurable intelligent surface, that redirects a second redirected instance of the impinging electromatic wave at a second beam direction that is different from the first beam direction.

11. The controllable resonator device of claim 8, wherein the redirected instance is a first redirected instance, wherein the reconfigurable intelligent surface is a first reconfigurable intelligent surface that redirects the first redirected instance of the impinging electromatic wave at a first beam direction with a first gain value, and further comprising a second reconfigurable intelligent surface, stacked below the first reconfigurable intelligent surface, that redirects a second redirected instance of the impinging electromatic wave at a second beam direction with a second gain value, wherein the first beam direction is different from the second beam direction, and the first beam gain value is different from the second beam gain value.

12. A method, comprising,
changing, by a system comprising at least one controller, a state of a unit cell of a reconfigurable intelligent surface from a non-resonating state to a resonating state, to redirect an electromagnetic wave impinging on the unit cell at an operating frequency of the unit cell to a target location, the changing comprising:
controlling application of a voltage or a current to selectively output a surface acoustic wave to a resonator of the unit cell, to change a state of a metal-insulator-transition resonator aperture portion of the resonator to a low resistance state in which the metal-insulator-transition resonator resonates at the operational frequency of the impinging electromatic wave to redirect a redirected instance of the impinging electromatic wave to the target location.

13. The method of claim 12, further comprising, changing, by the system, the state of the unit cell from the resonating state to the non-resonating state, comprising removing the application of the voltage or the current to halt the selective output of the surface acoustic wave to the resonator, to change the state of a metal-insulator-transition resonator aperture portion to a high resistance state in which metal-insulator-transition resonator does not resonate at the operational frequency of the impinging electromatic wave.

14. The method of claim 12, wherein the unit cell is part of a group of respective unit cells of a reconfigurable intelligent surface, and wherein the at least one controller controls respective low resistance or high resistance states of respective metal-insulator-transition resonator aperture portions of the respective unit cells to controllably create constructive interference of respective redirected instances that together reflect the impinging electromatic wave as a beam in a controlled reflection direction with a controlled gain.

15. A unit cell, comprising:
a ring resonator comprising metal-insulator-transition material;
a substrate beneath the ring resonator; and
a surface acoustic wave generator that is controlled to:
output a surface acoustic wave to travel atop the substrate and through the metal-insulator-transition material to change an aperture portion of the ring resonator to a low resistance state in which the ring resonator resonates in response to an electromagnetic wave impinging on the unit cell at a frequency corresponding to a resonating frequency of the ring resonator; and
halt the output of the surface acoustic wave to change the aperture portion of the ring resonator to a high resistance state in which the ring resonator does not resonate in response to the electromagnetic wave impinging on the unit cell.

16. The unit cell of claim 15, wherein the surface acoustic wave generator comprises an interdigitated capacitor comprising interleaved fingers.

17. The unit cell of claim 15, wherein the ring resonator is rectangular, wherein the surface acoustic wave generator comprises an interdigitated capacitor positioned parallel or substantially parallel to opposite sides of the ring resonator, and wherein the aperture portion of the ring resonator corresponds to the opposite sides of the ring resonator.

18. The unit cell of claim 15, wherein the unit cell is a respective unit cell of a group of respective unit cells of a reconfigurable intelligent surface, and wherein respective surface acoustic wave generators of the respective unit cells are independently controllable to redirect the electromagnetic wave impinging on the reconfigurable intelligent surface as a beam having beam parameters determined by respective low resistance or high resistance states of the respective unit cells.

19. The unit cell of claim 18, wherein the beam parameters comprise at least one of: a beam-steering angle, a beam gain, a beam frequency, a beam bandwidth, or a beam polarization.

20. The unit cell of claim 18, wherein the reconfigurable intelligent surface is a first reconfigurable intelligent surface of respective first unit cells, wherein the beam is a first beam having first beam parameters, wherein the respective low resistance or high resistance states are respective first low resistance or high resistance states of the respective first unit cells, and further comprising a second reconfigurable intelligent surface, stacked below the first reconfigurable intelligent surface, comprising respective second unit cells that are independently controllable from the respective first unit cells to redirect the electromagnetic wave impinging on the second reconfigurable intelligent surface as a second beam having second beam parameters determined by respective second low resistance or high resistance states of the respective second unit cells of the second reconfigurable intelligent surface.
